(19) United States
(12) Patent Application Publication
(10) Pub. No.: US 2007/0141806 A1
(43) Pub. Date: Jun. 21, 2007

(54) Method for producing group III nitride based compound semiconductor device

(75) Inventors: Toshiya Uemura, Aichi-ken (JP); Shigemi Horiuchi, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 11/633,619

(22) Filed: Dec. 5, 2006

(30) Foreign Application Priority Data
Dec. 6, 2005 (JP) 2005-352728

(51) Int. Cl. H01L 21/30; H01L 21/46

(52) U.S. Cl. 438/458

(57) ABSTRACT

The present invention relates to method for producing a group III nitride based compound semiconductor device. A plurality of group III nitride based compound semiconductor layers are epitaxially grown on a first substrate. An electrode is formed on the uppermost layer of the group III nitride based compound semiconductor layers, the electrode being formed of a first multi-layer including at least a layer for preventing migration of tin contained in a solder. A second multi-layer including at least a layer for preventing migration of tin contained in a solder is formed on a second substrate on which a semiconductor device is to be placed. The surface of the first substrate on which the electrode has been formed is joined to the surface of the second substrate on which the multi-layer has been formed by means of a solder containing at least tin. the first substrate removed from the group III nitride based compound semiconductor layers.

### BACKGROUND OF THE INVENTION

1. Field of the Invention

The present invention relates to a producing method for a group III nitride based compound semiconductor device. As used herein, the term “semiconductor optical device” collectively refers to a semiconductor device having any optical function of interest, including an energy conversion device for converting optical energy to electric energy or vice versa (e.g., a light-emitting device or a photoreceptor).

2. Background Art

It's been a long time since a group III nitride based compound semiconductor was found to be useful for producing a light-emitting device which emits green or blue light to UV light. Hitherto, such a light-emitting device has generally been produced through epitaxial growth of a group III nitride based compound semiconductor on an insulating hetero-substrate such as a sapphire substrate. Even when a conductive hetero-substrate is employed, considerable numbers of dislocations occurring during the growth remain in the formed epitaxial growth layer, which is problematic. In addition, while the epitaxial growth product is returned to ambient temperature, cracks attributed to difference in interlayer expansion coefficient are generated in a group III nitride based compound semiconductor layer, and the crack generation cannot be sufficiently prevented, which is also problematic.

Meanwhile, Japanese Patent No. 3418150, Japanese Kohyo Patent Publication Nos. 2001-501778 and 2005-522873, USP No. 6071795, and Kelly, et al., “Optical process for liftoff of group III-nitride films,” Physica Status Solidi (a) vol. 159(1997), p. R3-R4 disclose some techniques for producing semiconductor devices employing a substrate for epitaxial growth and a supporting substrate for use in a device, which are different from each other. Specifically, a group III nitride based compound semiconductor layer is epitaxially grown on a first substrate, and the produced group III nitride based compound semiconductor device is transferred to a second substrate.

### SUMMARY OF THE INVENTION

The present inventors have carried out extensive studies on employment of the above techniques for producing a group III nitride based compound semiconductor optical device. In the inventors'studies, a conductive substrate is employed as a supporting substrate, and an electrode bonded to a p-type layer being in contact with the supporting substrate is formed from a high-reflectance metal. In addition, on the opposite side, an electrode bonded to an n-type layer having a surface exposed through removal of a growth substrate is processed into a window frame form. Through employment of the inventors'technique, the light emitted from, for example, a group III nitride based compound semiconductor light-emitting device can be efficiently extracted through a window (i.e., area inside the window frame) where no frame-form electrode is provided on a surface of the n-type layer.

When the group III nitride based compound semiconductor light-emitting device is transferred to the supporting substrate from the epitaxial growth substrate, it is thought that the supporting substrate and the epitaxial growth substrate are bonded with each other once. In this case the bonded surface and the bonding material of them is preferably made of a conductive material, especially metal.

Thus, an object of the present invention is to improve the structure of a multi-conductive layer between the two substrates in the method of removing the epitaxial growth substrate after the supporting substrate is bonded to the epitaxial growth substrate once.

According to a first aspect of the present invention, there is provided a method for producing a group III nitride based compound semiconductor device, the method comprising:

epitaxially growing, on a first substrate, a plurality of group III nitride based compound semiconductor layers;

forming an electrode on the uppermost layer of the group III nitride based compound semiconductor layers, the electrode formed of a first multi-layer including at least a layer for preventing migration of tin contained in a solder;

forming, on a second substrate on which a semiconductor device is to be placed, a second multi-layer including at least a layer for preventing migration of tin contained in a solder;

joining, by means of a solder containing at least tin, the surface of the first substrate on which the electrode has been formed, to the surface of the second substrate on which the multi-layer has been formed; and

removing the first substrate from the group III nitride based compound semiconductor layers.

According to the second aspect of the present invention, the step of removing the first substrate includes decomposing a thin layer of a group III nitride based compound semiconductor through irradiation with a laser beam having such a wavelength that the beam penetrates the first substrate and is absorbed by a layer formed of the group III nitride based compound semiconductor.

According to the third aspect of the present invention, the layer for preventing migration of tin is formed from nickel or platinum.

According to the fourth aspect of the present invention, the device further includes a high-reflectance metal layer more proximal to the uppermost layer of the group III nitride based compound semiconductor layers than to the layer for preventing migration of tin. According to the fifth aspect of the present invention, the device further includes a layer formed of titanium between the layer for preventing migration of tin and the high-reflectance metal layer.

According to the sixth aspect of the present invention, the second substrate is a conductive silicon substrate.

According to the seventh aspect of the present invention, the method further comprises forming, on the second substrate, a layer from aluminum or titanium nitride.

According to the eighth aspect of the present invention, the multi-layer formed on the second substrate includes, between the layer formed from aluminum or titanium nitride and the layer for preventing migration of tin, a layer formed from titanium.

For example, the conductive substrate is preferably joined to the uppermost layer of the epitaxial growth layers on the epitaxial growth substrate by means of a conductive material such as a metal. In the final joining step, use of a solder is advantageous by virtue of excellent joining performance thereof at relatively low temperature. However, if the solder contains tin and the uppermost metal layer is formed of gold, tin migrates into gold. In some metal species such as nickel (Ni) and platinum (Pt), tin migrates at very low speed. Thus, when a multi-layer metal film including a metal layer in which tin migrates very slowly is provided on the second substrate and on the uppermost epitaxial growth layer on the first substrate, two wafers can readily be joined together by use of a tin-containing solder (first aspect) . After completion of joining, through removal of the epitaxial growth substrate (first substrate), a group III nitride based compound semiconductor device in which one electrode is connected to for example, a conductive substrate can be readily produced.

Removal of the epitaxial growth substrate (first substrate) is readily performed through irradiation with a laser beam having such a wavelength that the beam penetrates the substrate and is absorbed by a group III nitride based compound semiconductor layer (second aspect). Through the process, the group III nitride based compound semiconductor layer is melted and decomposed. For example, when the semiconductor is GaN, it is decomposed to droplets of Ga and N_{2.}

The layer for preventing migration of tin is preferably formed from nickel (Ni) or platinum (Pt) (third aspect). When the device further includes a high-reflectance metal layer more proximal to the uppermost layer of the group III nitride based compound semiconductor layers than to the layer for preventing migration of tin, a surface from which the first substrate has been removed can serve as a light-extraction region or a light-accepting region in a light-emitting device, a photoreceptor, or other optical devices (fourth aspect). When the device further includes a layer formed of titanium between the layer for preventing migration of tin and the high-reflectance metal layer, two metal layers having poor adhesion performance can be more readily joined together, as compared with the case in which the titanium layer is not provided (fifth aspect).

In a simple mode, the second substrate is a conductive silicon substrate (sixth aspect). In this case, when an aluminum layer or a titanium nitride (TiN) layer is formed on the substrate, a multi-layer metal film can be readily bonded to the silicon substrate at low contact resistance (seventh aspect). Through provision of a titanium layer between the layer formed from aluminum or titanium nitride and the layer for preventing migration of tin, the two substrates can be readily joined at high adhesion (eighth aspect).

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIGS. 1A to 1K show cross-sections of a group III nitride based compound semiconductor light-emitting device 1000 showing production steps therefor;

### DETAILED DESCRIPTION OF PREFERRED EMBODIMENTS

The present invention is applicable to any type of group III nitride based compound semiconductor optical device, particularly to a light-emitting device having a light extraction region, and a photoreceptor having a light-accepting region. In the semiconductor optical device having a supporting substrate, an electrode (e.g., a window-frame-shape or lattice pattern electrode) is preferably formed, directly or by the mediation of a transparent electrode, on a group III nitride based compound semiconductor layer provided on a surface not being in contact with the supporting substrate. Because positive and negative electrodes are provided so as to sandwich a light-emitting region in the present invention, the supporting substrate is preferably a conductive substrate. Otherwise with respect to the first substrate, i.e., an epitaxial growth substrate, an insulating substrate may be used because the device structure is transferred to the conductive substrate and the first substrate is removed.

In the case where a semiconductor layer is separated from the epitaxial growth substrate by melting and decomposing a semiconductor layer (e.g., a GaN thin film) through laser beam radiation, a laser beam having a wavelength shorter than 365 nm is preferably employed. Alternatively, YAG laser beams (wavelength: 365 nm and 266 nm), an XeCl laser beam (wavelength: 308 nm), an ArF laser beam (155 nm), and a KrF laser beam (wavelength: 248 nm) are preferably employed. The laser beam radiation area for one operation; i.e., a unit radiation area, may be a rectangular area having. a size of integral multiples of a chip size, in both the lateral and transverse directions. For example, when a chip (square) has a side of 500 μm, an unit radiation area of 2 mm×2 mm, which corresponds to an area including 4 ×4 chips, may be employed. Alternatively, a unit radiation area of 3 mm×3 mm, which corresponds to an area. including 6 ×6 chips, may be employed. Such a unit laser beam radiation area is continuously scanned on a wafer without overlapping radiation areas. Such operation is preferred, since contours of the unit radiation area do not remain in a chip area. In other words, a semiconductor-melted area and a semiconductor-non-melted area do not co-exist in one single chip area during one single laser beam radiation operation, whereby production yield and characteristics of devices can be enhanced.

The stacked structure of a group III nitride based compound semiconductor is preferably formed through epitaxial growth. A buffer layer, which is formed on a growth substrate prior to epitaxial growth, may be formed not through epitaxial growth but through other techniques such as sputtering. No particular limitation is imposed on the specific procedure of the growth method such as epitaxial growth, and no particular limitation is imposed on the type of the epitaxial growth substrate, layer configuration, layer structure of functional layers (MQW, SQW, cladding layer, guide layer, etc.) including a light-emitting layer, handling of divided devices, etc. Detailed descriptions of the layer structure and manufacturing method of the semiconductor stacked structure may be omitted in the Embodiment described hereinbelow. However, in the present invention, any of the structures and the techniques known at the time of the present application may be employed in combination. Unless otherwise mentioned, these known layer structures and techniques are incorporated into the present invention.

The term “group III nitride based compound” refers in a narrower sense to an AlGaInN-based 4-component (including 2-component and 3-component) semiconductor itself and, in a broader sense, to such a semiconductor to which a donor impurity element or an acceptor impurity element for imparting conductivity thereto has been added. However, in general, the above semiconductor compounds may further contain another group III element or group V element as an additional or substituted element, or may contain any additional element for imparting other functions thereto. These group III nitride based compounds are not excluded.

The electrode to be joined to the group III nitride based compound layer, and a single-layer or multi-layer electrode to be connected with the above electrode may be formed from any conductive material. Generally, a semiconductor optical device has a pair consisting of positive and negative electrodes. One of the above electrodes may be formed from a high-reflectance metal. Iridium (Ir), platinum (Pt), rhodium (Rh), silver (Ag), aluminum(Al), palladium(Pd), an alloy including at least one thereof as a main component, or a multi-layer thereof can be suitably used as the high-reflectance metal when high-reflectance metal is directly deposited on the group III nitride based compound layer. A transparent electrodes can be used such as an oxide electrode such as an indium tin oxide electrode or an indium titanium oxide electrode provided on the semiconductor layer. And also the high-reflectance metal may be provided on the oxide electrode. When the electrode layer is formed from a metal layer and an oxide (e.g., ITO) layer, a dielectric layer formed of any dielectric material may be provided between the oxide layer and the metal layer in order to avoid direct contact therebetween. In this case, grooves are provided in the dielectric layer, and the metal layer and the oxide (e.g., ITO) layer may be electrically connected through the grooves, which are filled with conductive material. The epitaxial growth wafer and the supporting substrate are preferably joined together by use of a solder. Depending on the composition of the solder, a multi-layer metal film is preferably provided, in accordance with needs, on the joint surface of the supporting substrate or the epitaxial growth wafer.

### Embodiment 1

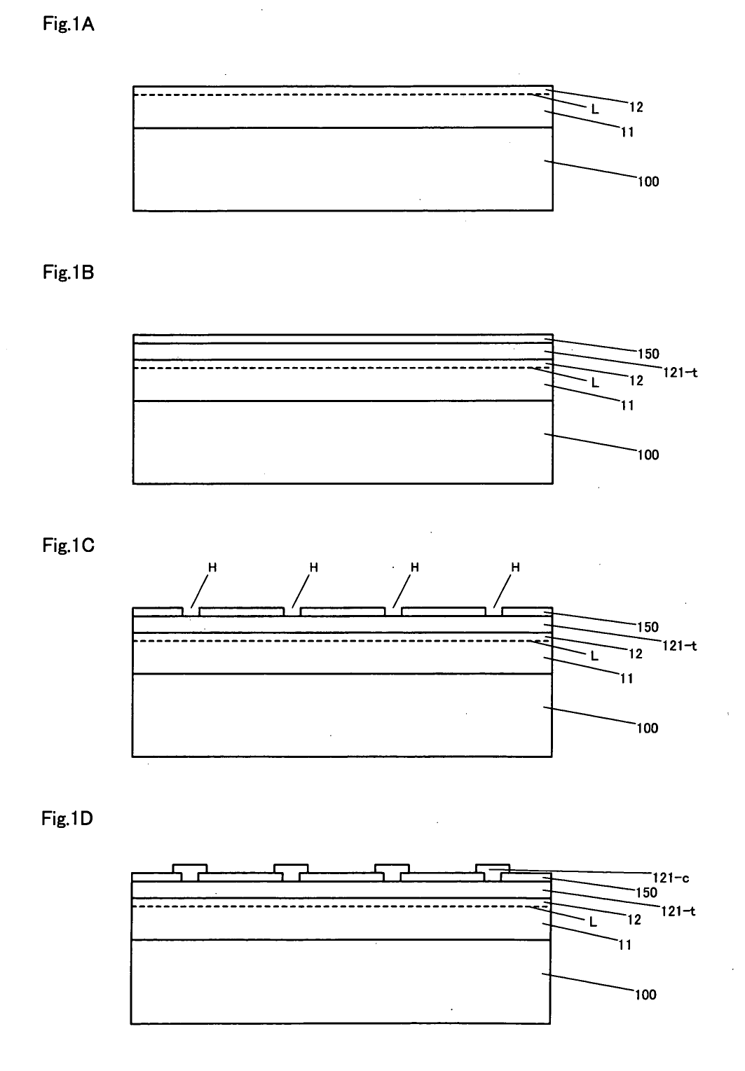

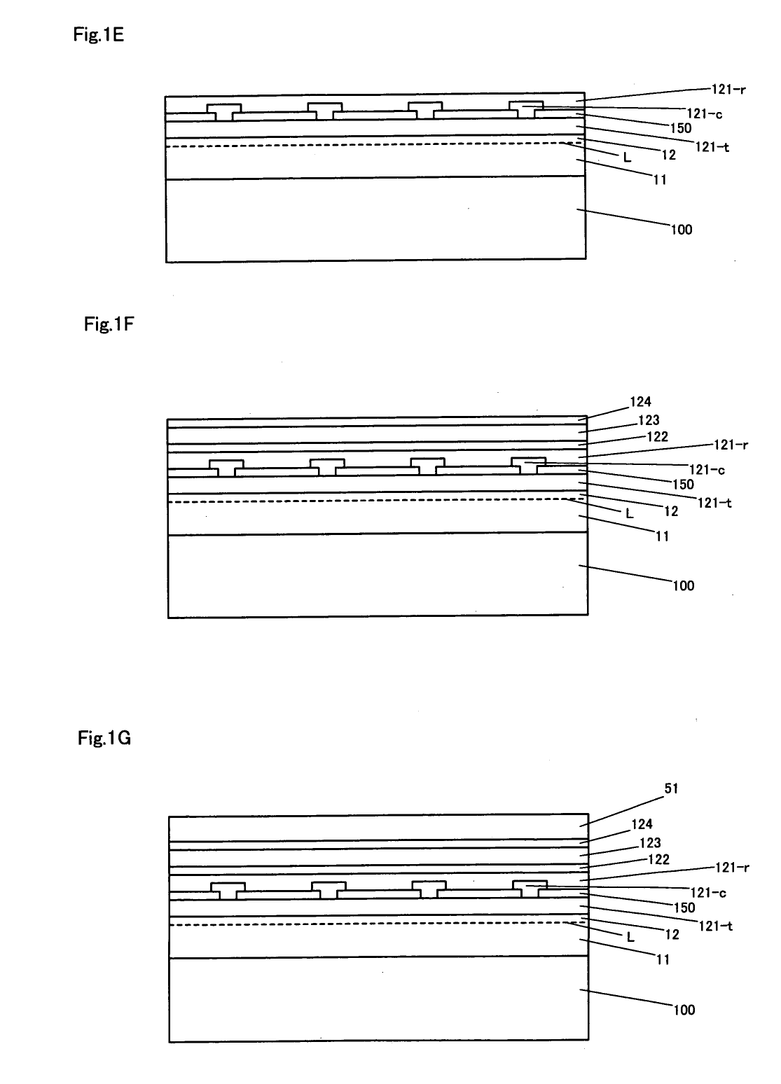

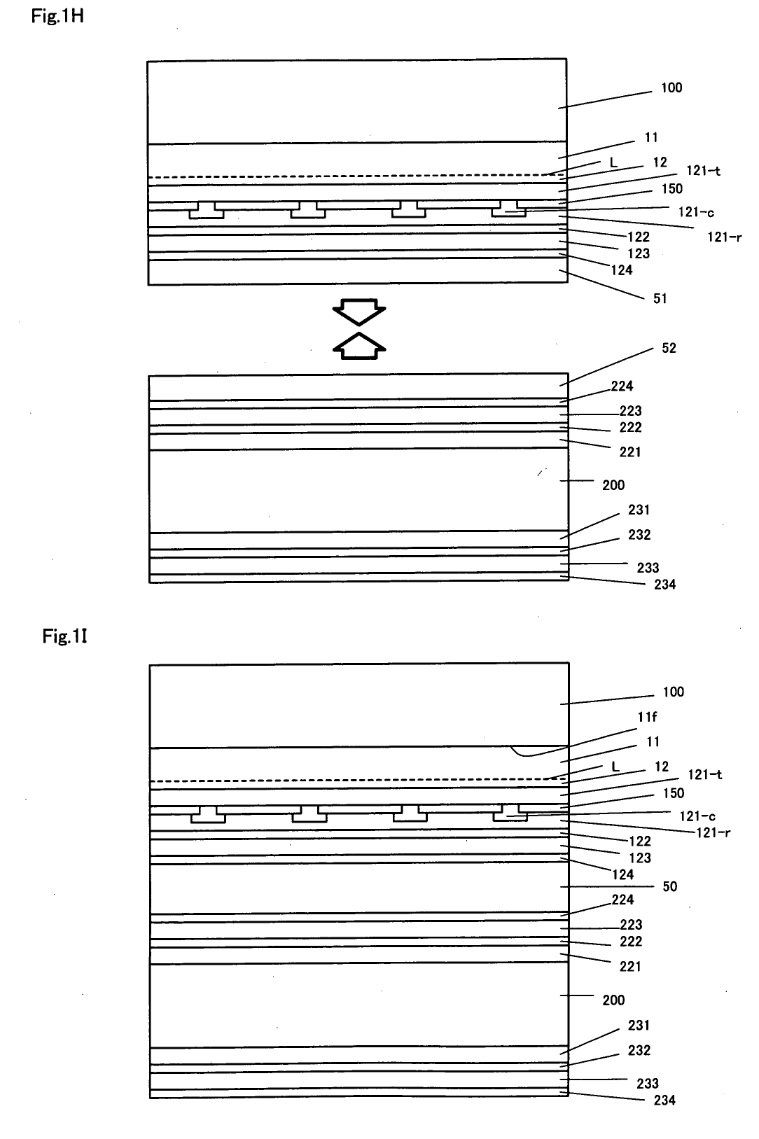

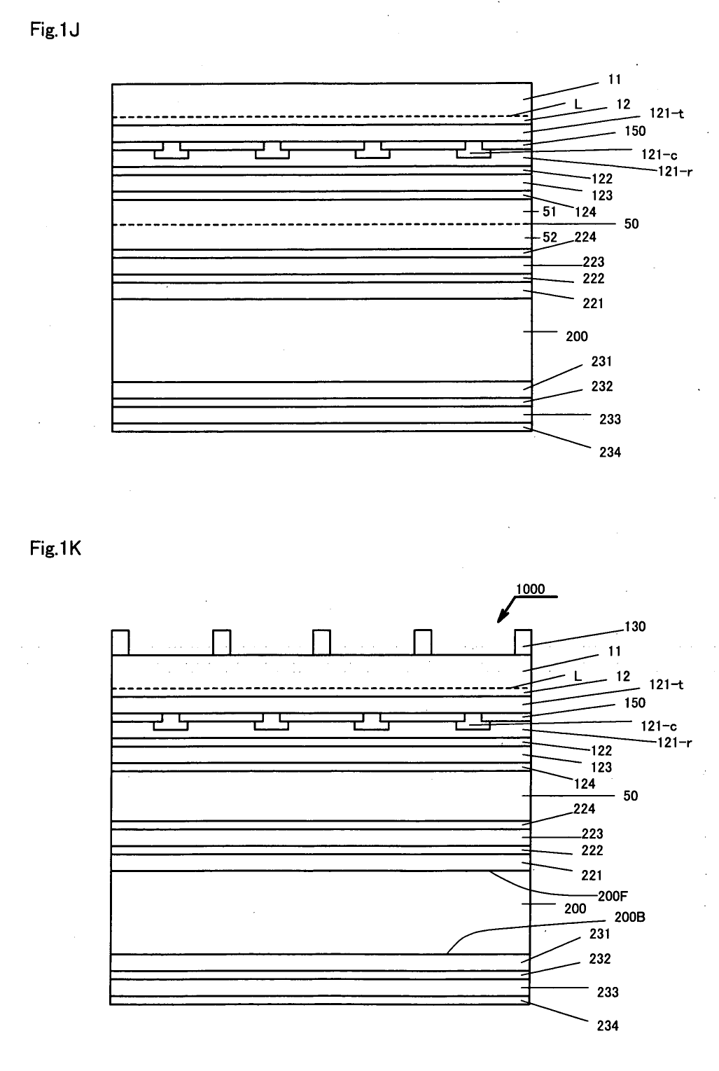

FIGS. 1A to 1K show cross-sections of a group III nitride based compound semiconductor light-emitting device 1000 in the production steps according to one embodiment of the present invention. FIG. 1K shows one chip of the group III nitride based compound semiconductor light-emitting device 1000. FIGS. 1A to 1J show cross-sections of one chip of the device, and enlarged cross-sections of one single wafer. FIG. 1K shows enlarged cross-sections of one single wafer before dicing into chips.

Firstly, a sapphire substrate 100 is provided, and a group III nitride based compound semiconductor layer is formed on the substrate through routine epitaxial growth (FIG. 1A). FIG. 1A shows the group III nitride based compound semiconductor layer as a simplified stacked structure including an n-type layer 11 and a p-type layer 12 with a light-emitting region L. In FIGS. 1A to 1K, the n-type layer 11 and the p-type layer 12 are shown as two layers in contact with each other at the light-emitting region L represented by a broken line, and detailed stacked structures are not provided. For example, on the sapphire substrate 100, there is formed a stacked structure including a buffer layer, a silicon-doped GaN high-concentration n⁺ layer, a GaN low-concentration n-type layer, and an n-AlGaN cladding layer, which are formed in this order. In this case, the stacked structure is represented by only the n-type layer 11 in FIGS. 1A to 1K. Similarly, a stacked structure including a magnesium-doped p-AlGaN cladding layer, a GaN low-concentration p-type layer, and a GaN high-concentration p⁺ layer, which are formed in this order, is represented by only the p-type layer 12 in FIGS. 1A to 1K. The light-emitting region L, which is represented by a broken line, indicates both a pn-junction face and, for example, a multiple-quantum well light-emitting layer (well layers are generally undoped). Thus, the light-emitting region L does not simply represent the interface between the n-type layer 11 and the p-type layer 12. The “plane of the light-emitting region” refers to a plane present near the light-emitting region L represented by a broken line. Before performance of “the below-mentioned heat treatment under nitrogen (N₂) atmosphere,” the p-type layer 12 is a layer containing a p-type impurity element but electric resistance thereof is not lowered. After completion of “the heat treatment under nitrogen (N₂) atmosphere,” the p-type layer 12 is a general low-resistance p-type layer.

Subsequently, a transparent electrode 121-t comprising an indium tin oxide (ITO) was formed on the entire surface of the p-type layer 12 in thickness of 300 nm by an electron beam deposition. The thus-processed stacked body was heated at 700° C. under N₂ environment for five minutes, to thereby lower the resistance of the p-type layer 12 and lower the contact resistance of the p-type layer 12 and the ITO electrode 121-T. Subsequently, a dielectric layer 150 made of silicon nitride (SiNₓ) was formed on the entire surface of the ITO electrode 121-t in thickness of 100 nm (FIG. 1B).

Subsequently, grooves H was formed in the dielectric layer 150 comprising silicon nitride (SiNₓ) by a dry etching and photolithography techniques using a photo resist film (not shown). As described hereinafter the figure and position of the grooves H, i.e., the figure and position of a connection part 121-c made of nickel(Ni), are not coincided with the figure and position of n-electrode 130 comprising a multi-electrode film to be formed after on the projection thereof on the surface of the light emitting region L. In the embodiment 1 the grooves H have a lattice pattern whose stripe has the width of 20 μm and the repetition period of 80 μm to 100 μm in the group III nitride based compound semiconductor light-emitting device 1000 with a square of 400 μm to 500 μm. The photo resist film was removed after those process and the device 100 was obtained as shown in FIG. 1C.

Subsequently, a photo resist film which is not shown was formed on the dielectric layer 150 in order to form the connection part 121-c made of nickel(Ni) in the grooves H. Grooves whose width was wider than that of the grooves H made in the dielectric layer 150 comprising SiNₓwere made in this photo resist film. Nickel(Ni) was vapor-deposited and formed in the grooves H of dielectric layer 150 comprising SiNₓ and the grooves of the photo resist film. At this time, nickel(Ni) was filled the grooves H of the dielectric layer 150 comprising SiNₓ and was vapor-deposited until eaves of thickness of 20μm was formed on the dielectric layer 150 around the grooves H. In this way, the resist film was removed and the connection part 121-c which was made of nickel(Ni) filled in the grooves H of the dielectric layer 150 comprising SiN_{X} was formed as shown in FIG. 1D.

Subsequently, The high-reflectance metal layer 121-r comprising aluminum (Al) with the thickness of 300μm was formed by a vapor deposition on the dielectric layer 150 comprising SiNₓ which had the connection part 121-c made of nickel(Ni) in the grooves H as shown in FIG. 1E. In this way, multi-p-electrode which does not absorb a light and has high-reflectance and high-adhesiveness to the group III nitride based compound semiconductor layer was made. Those characteristics depend on the multi-structure comprising the transparent electrode 121-t made of an indium tin oxide (ITO), the connection part 121-c made of nickel(Ni) and the high-reflectance metal layer 121-r made of aluminum (Al). Here, the role of the dielectric film 150 formed of SiNₓ, which has the connection part 121-c made of nickel(Ni) in the grooves H, is to prevent aluminum (Al) and indium tin oxide (ITO) from contacting with each other and to keep electrode characteristic from deteriorating by oxidization of aluminum (Al).

Next will be described formation of a multi-layer metal film through vapor deposition. Specifically, a titanium (Ti) layer 122 (thickness: 50 nm), a nickel (Ni) layer 123 (thickness: 500 nm), and a gold (Au) layer 124 (thickness: 50 nm) are sequentially formed, to thereby provide a layer structure as shown in FIG. 1F. The functions of the titanium (Ti) layer 122, nickel (Ni) layer 123, and gold (Au) layer 124 are as follows. The gold (Au) layer 124 serves as a layer for alloying with a 20%-tin gold-tin solder (Au-20Sn) 51 to be provided. The nickel (Ni) layer 123 prevents migration of tin (Sn) to the aluminum (Al) high-reflectance electrode 121-r. The titanium (Ti) layer 122 enhances adhesion with respect to the nickel (Ni) layer 123 and the aluminum (Al) high-reflectance electrode 121-r.

On the gold (Au) layer 124, a 20%-tin gold-tin solder (Au-20Sn) layer 51 having a thickness of 3,000 nm is provided (FIG. 1G).

Next, an n-type silicon substrate 200 serving as the second substrate, i.e., a supporting substrate, is provided. On each surface of the substrate, a multi-layer conductive film is formed through vapor deposition or a similar process. Specifically, layers to be formed on the surface of supporting substrate which is joined to the gold-tin solder (Au-20Sn) 51 (hereinafter referred to as a front surface) are denoted by reference numerals 221 to 224, and layers to be formed on the back surface of the substrate are denoted by reference numerals 231 to 244. On each surface of the silicon substrate 200, a titanium nitride (TiN) layer (thickness: 30 nm) 221 or 231, a titanium (Ti) layer (thickness: 50 nm) 222 or 232, a nickel (Ni) layer (thickness 500 nm) 223 or 233, and a gold (Au) layer (thickness: 50 nm) 224 or 234 were formed. The titanium nitride (TiN) layers 221 and 231 are employed by virtue of low contact resistance with respect to the n-type silicon substrate 200. The functions of the titanium (Ti) layers 222 and 232, those of the nickel (Ni) layers 223 and 233, and those of the gold (Au) layers 224 and 234 are completely the same as those of the aforementioned titanium (Ti) layer 122, nickel (Ni) layer 123, and gold (Au) layer 124, respectively. On the gold (Au) layer 224, serving as the uppermost layer of the multi-layer conductive film provided on the front surface of the n-type silicon substrate 200, a 20%-tin gold-tin solder (Au-20Sn) layer 52 having a thickness of 1,500 nm was formed. The tin 20% gold-tin solder (Au-20Sn) 51 having a thickness of 1,500 nm shown in FIG. 1G is joined to the gold-tin solder (Au-20Sn) 52, whereby the wafer of the group III nitride based compound semiconductor light-emitting device is joined to the n-type silicon substrate 200 as shown in FIG. 1H. Through hot-pressing at 300° C. and 30 kgf/cm² (2.94 MPa), the two wafers are combined. Hereinafter, the gold-tin solder (Au-20Sn) will be denoted by reference numeral 50 as a unified layer (FIG. 1I).

The sapphire substrate 100 of the thus-combined wafer is irradiated with a KrF high-power pulse laser beam (248 nm). The employed irradiation conditions were an energy density of 0.7 J/cm² or higher, a pulse width of 25 ns, a unit radiation area of 2 mm×2 mm or 3 mm×3 mm, and a scanning period in the transverse direction of 10 Hz. The laser beam was continuously scanned over the sapphire substrate 100 in such a way of preventing from overlapping unit radiation areas. Timing of each radiation operation is determined such that contours of the unit radiation area do not exist in a single device chip. In other words, a contour of the unit radiation area is preferably present in a dicing line, which is a chip separation region. Through the laser radiation, the interface 11f between the n-type layer 11 (GaN layer) and the sapphire substrate 100 is melted in the form of thin film, to thereby decompose to form gallium (Ga) droplets and nitrogen (N₂). Thereafter, the sapphire substrate 100 is removed through the lift-off process from the combined wafer as shown in FIG. 1J. The thus-exposed surface of the n-type layer 11 is washed with dilute hydrochloric acid, to thereby remove gallium (Ga) droplets deposited on the surface.

In the subsequent step, a photo resist film (not illustrated) is formed over the exposed surface of the n-type layer 11. Through photolithography, the photo resist film is patterned to form a groove with a lattice pattern in each device chip. The lattice pattern is not coincided with the figure and position of the connection part 121-c to be formed after on the orthogonal projection thereof on the surface of the light emitting region L. On the window frame or lattice pattern grooves of the photo resist film, a multi-layer metal film serving as an n-electrode 130 is formed through vapor deposition. Specifically, on the n-type layer 11, a vanadium (V) layer (thickness: 15 nm), an aluminum (Al) layer (thickness: 150 nm), a titanium (Ti) layer (thickness: 30 nm), a nickel.(Ni) layer (thickness: 500 nm), and a gold (Au) layer (thickness: 500 nm) were sequentially formed. Thereafter, the resist was removed through the lift-off process, to thereby leave an n-electrode 130 formed of a multi-layer metal film in the lattice pattern grooves of the resist film. In this process, the remaining metal film is removed with the photo resist.

Thus, the produced light-emitting device has the n-type silicon substrate 200 serving as a supporting substrate on each surface of which a conductive multi-layer film is formed; the transparent electrode 121-t comprising ITO, the dielectric layer 150 comprising silicon nitride (SiNₓ), the connection part 121-c comprising nickel (Ni) which is filled in the grooves H formed in the dielectric layer 150, the high-reflectance metal layer 121-r comprising aluminum (Al), the titanium layer 122 which is formed on the layer 121-r, those multi-layer serving as a p-electrode layer on the p-type layer 12; and a multi-layer metal film formed on the titanium layer 122. The p-type layer 12 is electrically connected, via the multi-layer metal film by the mediation of the gold-tin solder (Au-20Sn) 50, to the n-type silicon substrate 200 (FIG. 1K). Each group III nitride based compound semiconductor light-emitting device 1000 has a frame-form or lattice pattern n-electrode 130 at the surface of the n-type layer 11, and the region except for the n-electrode 130 is a light-extraction region on the n-type side. The p-electrode is electrically connected to the back surface 200B of the silicon substrate 200 through the silicon substrate 200.

Then, respective devices are formed to break up by arbitrary method. For example, the substrate 200 is divided into chips by breaking after it is half-cut by means of dicing blade. Certain level of the back surface 200B of silicon substrate 200 is half-cut. On the other hand, at the side of n-type layer 11 and p-type layer 12 of the epitaxial layer may be cut completely at least near the parting line. The cutting does not always have to reach to the surface 200F of the silicon substrate 200. [About the planar shapes of the n-type electrode 130 and the groove H of the dielectric layer 150 which is the connection part 121-c filled with nickel (Ni)]

It is preferable that the planar shapes of the filled groove H of the dielectric layer 150, i.e., the connection part 121-c, and the planar shape of n-electrode 130, that is, the their orthogonal projections on the flat surface of the light emitting region L, are not overlapped. And the orthogonal projections are preferably to keep a certain distance at any position. For “a certain distance” in this case is, for example, the total thickness of n-type layer 11 and p-type layer 12, or several times of this thickness. If the total thickness of n-type layer 11 and p-type layer 12 is 5 μm, the two orthogonal projections need to be separated by not less than 5 μm, and more preferable to be separated by not less than 10 μm, and further preferable to be separated by not less than 20 μm.

In the embodiment 1, the multi-layer structure comprising the dielectric layer 150, the connection part 121-c formed by the grooves H filled with nickel (Ni), the transparent electrode 121-t and the layer 121-r comprising aluminum (Al) of high-reflectance metal is used. However, they may be alternatively formed by a single layer of high-reflectance metal, for example, layer of rhodium (Rh), silver (Ag) or platinum (Pt).

In Embodiment 1, with respect to the high-reflectance metal layer 121-r, instead of the aluminum (Al), iridium (Ir), platinum (Pt), rhodium (Rh), silver (Ag), palladium(Pd), an alloy including at least one thereof as a main component, or a multi-layer thereof may be used. Also with respect to the connection part 121-c, instead of the nickel (Ni), chromium (Cr), molybdenum (Mo), tantalum (Ta), titanium (Ti), vanadium (V), tungsten (W), an alloy including at least one thereof as a main component, or a multi-layer thereof may be used. Also with respect to the layer 123 for preventing migration of tin into the high-reflectance metal layer 121-r, instead of the nickel (Ni), platinum (Pt) may be used. In the embodiment 1, a two-layer electrode structure which comprises a transparent electrode formed of an indium tin oxide(ITO) electrode or an indium titanium oxide electrode provided on the P-type layer 12 and a high-reflectance metal layer comprising silver(Ag) formed on the transparent electrode, may be used instead of the electrode layers 121-t to 121-r.

In Embodiment 1, the n-electrode 130 is directly formed on the n-type layer 11. However, a window-frame-form or lattice pattern n-electrode may be formed after formation of, for example, a transparent electrode.

What is claimed is:

1. A method for producing a group III nitride based compound semiconductor device, the method comprising:
epitaxially growing, on a first substrate, a plurality of group III nitride based compound semiconductor layers;
forming an electrode on the uppermost layer of the group III nitride based compound semiconductor layers, the electrode formed of a first multi-layer including at least a layer for preventing migration of tin contained in a solder;
forming, on a second substrate on which a semiconductor device is to be placed, a second multi-layer including at least a layer for preventing migration of tin contained in a solder;
joining, by means of a solder containing at least tin, the surface of the first substrate on which the electrode has been formed, to the surface of the second substrate on which the multi-layer has been formed; and
removing the first substrate from the group III nitride based compound semiconductor layers.

2. A method for producing a group III nitride based compound semiconductor device as described in claim 1, wherein the step of removing the first substrate includes decomposing a thin layer of a group III nitride based compound semiconductor through irradiation with a laser beam having such a wavelength that the beam penetrates the first substrate and is absorbed by a layer formed of the group III nitride based compound semiconductor.

3. A method for producing a group III nitride based compound semiconductor device as described in claim 1, wherein the layer for preventing migration of tin is formed from nickel or platinum.

4. A method for producing a group III nitride based compound semiconductor device as described in claim 2, wherein the layer for preventing migration of tin is formed from nickel or platinum.

5. A method for producing a group III nitride based compound semiconductor device as described in claim 1, wherein the device further includes a high-reflectance metal layer more proximal to the uppermost layer of the group III nitride based compound semiconductor layers than to the layer for preventing migration of tin.

6. A method for producing a group III nitride based compound semiconductor device as described in claim 2, wherein the device further includes a high-reflectance metal layer more proximal to the uppermost layer of the group III nitride based compound semiconductor layers than to the layer for preventing migration of tin.

7. A method for producing a group III nitride based compound semiconductor device as described in claim 3, wherein the device further includes a high-reflectance metal layer more proximal to the uppermost layer of the group III nitride based compound semiconductor layers than to the layer for preventing migration of tin.

8. A method for producing a group III nitride based compound semiconductor device as described in claim 1, wherein the device further includes a layer formed of titanium between the layer for preventing migration of tin and the high-reflectance metal layer.

9. A method for producing a group III nitride based compound semiconductor device as described in claim 2, wherein the device further includes a layer formed of titanium between the layer for preventing migration of tin and the high-reflectance metal layer.

10. A method for producing a group III nitride based compound semiconductor device as described in claim 3, wherein the device further includes a layer formed of titanium between the layer for preventing migration of tin and the high-reflectance metal layer.

11. A method for producing a group III nitride based compound semiconductor device as described in claim 4, wherein the device further includes a layer formed of titanium between the layer for preventing migration of tin and the high-reflectance metal layer.

12. A method for producing a group III nitride based compound semiconductor device as described in claim 7, wherein the device further includes a layer formed of titanium between the layer for preventing migration of tin and the high-reflectance metal layer.

13. A method for producing a group III nitride based compound semiconductor device as described in claim 1, wherein the second substrate is a conductive silicon substrate.

14. A method for producing a group III nitride based compound semiconductor device as described in claim 1, which further comprises forming, on the second substrate, a layer from aluminum or titanium nitride.

15. A method for producing a group III nitride based compound semiconductor device as described in claim 3, which further comprises forming, on the second substrate, a layer from aluminum or titanium nitride.

16. A method for producing a group III nitride based compound semiconductor device as described in claim 7, which further comprises forming, on the second substrate, a layer from aluminum or titanium nitride.

17. A method for producing a group III nitride based compound semiconductor device as described in claim 12, which further comprises forming, on the second substrate, a layer from aluminum or titanium nitride.

18. A method for producing a group III nitride based compound semiconductor device as described in claim 14, wherein the multi-layer formed on the second substrate includes, between the layer formed from aluminum or titanium nitride and-the layer for preventing migration of tin, a layer formed from titanium.

19. A method for producing a group III nitride based compound semiconductor device as described in claim 16, wherein the multi-layer formed on the second substrate includes, between the layer formed from aluminum or titanium nitride and the layer for preventing migration of tin, a layer formed from titanium.

20. A method for producing a group III nitride based compound semiconductor device as described in claim 17, wherein the multi-layer formed on the second substrate includes, between the layer formed from aluminum or titanium nitride and the layer for preventing migration of tin, a layer formed from titanium.
